(19) United States
(12) Patent Application Publication
(10) Pub. No.: US 2009/0309127 A1
(43) Pub. Date: Dec. 17, 2009

(54) SELECTIVE AREA EPITAXY GROWTH METHOD AND STRUCTURE

(75) Inventors: JAMES W. RARING, Goleta, CA (US); Daniel F. Feezell, Goleta, CA (US); SHUJI NAKAMURA, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: SORAA, INC., Goleta, CA (US); KAAI, INC., Goleta, CA (US)

(21) Appl. No.: 12/482,440

(22) Filed: Jun. 10, 2009

Related U.S. Application Data
(60) Provisional application No. 61/061,521, filed on Jun. 13, 2008.

(51) Int. Cl. H01L 33/00; H01L 29/12; C30B 25/02

(52) U.S. Cl. 257/103; 257/613; 117/106; 257/E29.068; 257/E33.013

(57) ABSTRACT

A gallium containing crystalline material. The material comprises a bulk semi-polar gallium indium containing crystalline material having a thickness of about 20 nanometers to about 1000 nanometers. The material includes a spatial width dimension of no greater than about 10 microns characterizing the thickness of the bulk semi-polar gallium indium containing crystalline material. The material includes a photoluminescent characteristic of the crystalline material having a first wavelength, which is at least five nanometers greater than a second wavelength, which is derived from an indium gallium containing crystalline material grown on a growth region of greater than about 15 microns.

### CROSS-REFERENCES TO RELATED APPLICATIONS

This application claims priority to U.S. Provisional Application No. 61/061,521, filed Jun. 13, 2008, entitled “SELECTIVE AREA EPITAXY GROWTH METHOD AND STRUCTURE,” by inventors James W. Raring, Daniel F. Feezell, and Shuji Nakamura commonly assigned, and incorporated by reference herein for all purposes.

### BACKGROUND OF THE INVENTION

The present invention is directed to optical devices and related methods. More particularly, the present invention provides a method and device for emitting electromagnetic radiation using non-polar or semipolar gallium containing substrates such as GaN, MN, InN, InGaN, AlGaN, and AlInGaN, and others. Merely by way of example, the invention can be applied to optical devices, lasers, light emitting diodes, solar cells, photoelectrochemical water splitting and hydrogen generation, photodetectors, integrated circuits, and transistors, among other devices.

In the late 1800's, Thomas Edison invented the lightbulb. The conventional lightbulb, commonly called the “Edison bulb,” has been used for over one hundred years. The conventional light bulb uses a tungsten filament enclosed in a glass bulb sealed in a base, which is screwed into a socket. The socket is coupled to an AC power source or a DC power source. The conventional light bulb can be found commonly in houses, buildings, and outdoor lighting applications, and other areas requiring light. Unfortunately, drawbacks exist with the conventional Edison light bulb. That is, the conventional light bulb dissipates much thermal energy leading to inefficiencies. More than 90% of the energy used for the conventional light bulb dissipates as thermal energy. Additionally, the conventional light bulb routinely fails often due to thermal expansion and contraction of the filament element.

To overcome some of the drawbacks of the conventional light bulb, fluorescent lighting has been developed. Fluorescent lighting uses an optically clear tube structure filled with a halogen gas. A pair of electrodes is coupled between the halogen gas and couples to an alternating power source through a ballast. Once the gas has been excited, it discharges to emit light. Often times, the optically clear tube is coated with phosphor materials. Many building structures use fluorescent lighting and, more recently, fluorescent lighting has been fitted onto a base structure, which couples into a standard socket.

Solid state lighting techniques have also been used. Solid state lighting relies upon semiconductor materials to produce light emitting diodes, commonly called LEDs. At first, red LEDs were demonstrated and introduced into commerce. Red LEDs use Aluminum Indium Gallium Phosphide (or AlInGaP) semiconductor materials. Most recently, Shuji Nakamura pioneered the use of InGaN materials to produce LEDs emitting light in the blue color range for blue LEDs. The blue colored LEDs lead to innovations such as the BlueRay™ DVD player, solid state white lighting, and other developments. Other colored LEDs have also been proposed.

High intensity green LEDs based on GaN have been proposed and even demonstrated with limited success. Unfortunately, achieving high intensity, high-efficiency GaN-based green LEDs has been problematic. The performance of optolectronic devices fabricated on conventional c-plane GaN suffer from strong internal polarization fields, which leads to poor radiative recombination efficiency. Since this phenomenon becomes more pronounced in InGaN layers with increased indium content for increased wavelength emission, extending the performance of GaN-based LEDs to the green regime has been difficult. Furthermore, increased indium content in a GaN film often requires reduced growth temperature leading to poorer crystal quality of high-indium-content InGaN films. The difficulty of achieving a high intensity green LED has lead scientists and engineers to the term “green gap” to describe the generally unavailability of such green LED. These and other limitations may be described throughout the present specification and more particularly below.

From the above, it is seen that techniques for improving optical devices is highly desired.

### BRIEF SUMMARY OF THE INVENTION

According to the present invention, techniques related generally to optical devices are provided. More particularly, the present invention provides a method and device for emitting electromagnetic radiation using non-polar or semipolar gallium containing substrates such as GaN, MN, InN, InGaN, AlGaN, and AlInGaN, and others. Merely by way of example, the invention can be applied to optical devices, lasers, light emitting diodes, solar cells, photoelectrochemical water splitting and hydrogen generation, photodetectors, integrated circuits, and transistors, among other devices.

The present invention provides an approach for producing high-In-content (>5%) In containing layers such as InGaN, InAlN, InAlGaN in GaN-based light emitting devices such as laser diodes and light emitting diodes (LEDs) on nonpolar and semipolar GaN substrates. The growth of quality In-containing layers such as InGaN with sufficient In content to achieve emission wavelengths beyond 400 nm to the blue, green, yellow and red regime has historically been difficult [1]. This difficulty manifests itself with a reduction of material quality as the MOCVD reactor growth conditions are changed to facilitate increased-In-content InGaN. More specifically, the reduced growth temperatures required to prevent In evaporation are known to lead to poor crystal quality. The microstructural nature of the degraded material is a contentious topic as some research groups attribute it to compositional In fluctuations, while others claim it is a result of localized strain. In any case, the poor material quality has prevented the demonstration of an efficient laser diode at wavelengths beyond 400 nm.

Here we propose to use selective area epitaxy (SAE) to achieve increased-In-content InGaN layers without changing the MOCVD reactor growth conditions. That is, for the same growth pressure, temperature, and partial pressures of the In and Ga precursors, the solid composition of the InGaN film will possess higher In levels. This technique will enable increased temperature growth conditions to avoid the low temperatures conditions commonly used for increased-In-content InGaN) that are known to degrade crystal quality. In SAE, a dielectric (SiO₂, SiₓN_{y}, etc) mask is deposited on the substrate surface, lithographically patterned, and then etched such that various geometries of exposed semiconductor are realized. For laser diode fabrication the geometry of the unmasked area is often a long (100s of microns) narrow (1-5 microns) stripe. When subjected to epitaxial growth in an MOCVD reactor where the group-III precursors have a high surface and gas phase mobility, growth initiation can be prevented in the masked areas. A growth rate enhancement is observed in the unmasked areas adjacent to the dielectric mask from the increased concentration of the growth rate limiting group-III (In and Ga) adatoms within these areas. The lack of depletion of the group-III precursor molecules in the gas phase over the masked regions coupled with the high surface mobility of the group-III adatoms on the masked areas leads to an increased concentration of the group-III adatoms present in the growth area adjacent to the dielectric mask boundary. A key aspect of our invention is that the difference between the diffusion properties of the In and Ga precursors leads to In-enrichment in the InGaN layer adjacent to the dielectric mask. The metalorganic compounds trimethylindium (TMIn) and trimethylgallium (TMGa) are often used as the source material for In and Ga, respectively. Other source materials include triethylgallium, commonly known as TEGa, among others. The TMIn molecule decomposes more efficiently than TMGa in the high temperature MOCVD growth conditions, leading to a reduced average size of the In containing metalorganic molecules. Since the gas-phase diffusion coefficient increases with reduced molecule size, the In precursors will have a higher diffusivity and will therefore more readily arrive in the growth areas. The result is a relatively higher In content in the In and Ga containing layer (i.e. InGaN) adjacent to the dielectric mask for a given set of reactor conditions. The kinetics of SAE are a well understood phenomenon in traditional alloys such as InGaAs and InGaAsP [2]. Literature reports similar phenomenon on polar GaN, where researchers have grown InGaN quantum dots and multi-color LEDs using SAE.

According to an embodiment of the present invention, SAE is used to overcome the formidable challenge of realizing high-In-content InGaN quantum wells for the fabrication of high-efficiency laser diodes and LEDs with extended wavelengths beyond 450 nm into the blue, green, yellow and red regimes. The implementation of SAE will facilitate increased In incorporation in the In containing layer such as InGaN quantum wells adjacent to the masked region under identical growth conditions. This technique will be executed on nonpolar and/or semipolar GaN substrates to facilitate high-efficiency long-wavelength laser diodes and LEDs. Lasers and LEDs fabricated on conventional polar (c-plane) GaN suffer from internal piezoelectric and spontaneous polarization fields that intrinsically reduce the radiative recombination efficiency of electron-hole pairs and limit the device performance [3,4]. Early demonstrations of laser diodes fabricated on nonpolar (m-plane) GaN substrates operating at 405 nm and 451.8 nm show great promise for enhanced device performance [5, 6]. Furthermore, high-power green (516 nm) light emitting diodes (LED) fabricated on semipolar substrates indicate a natural tendency for increased In-incorporation on these crystallographic planes [7]. By coupling this enhanced In-incorporation behavior with minimized internal piezoelectric and spontaneous fields on semipolar substrates with our proposed SAE method for increased In-incorporation, our invention will enable the fabrication of high-efficiency blue, green, yellow and red emitting laser diodes and LEDs.

Laser diodes will be fabricated by patterning a dielectric mask either directly on the nonpolar/semipolar substrate or on an n-doped layer grown on the said substrates to form narrow stripes of unmasked growth area. The wafers will then be subjected to MOCVD growth where growth will initiate with an n-type GaN cladding layer, followed by the active region containing In containing quantum wells such as InGaN. The growth of the InGaN quantum wells in these narrow unmasked stripe areas will result in high-In-content quantum wells based on the SAE kinetics discussed above, pushing the emission wavelength to values required for blue, green, yellow and red emission. After deposition of the active region layers, the growth can be continued to deposit the p-GaN upper cladding layer or the growth can be interrupted. In the latter case, the sample would be removed from the reactor, the dielectric mask selectively etched, and the sample would be subjected to a regrowth for the definition of the p-cladding layer to realize a buried stripe laser structure. In the former case, where the p-cladding is defined in the same growth as the active region, surface ridge laser architectures could be easily fabricated from the resulting epitaxial structure.

LEDs will be fabricated in a very similar fashion to the lasers discussed above, however long stripe geometries will no longer be required because there is no need for in-plane optical guiding. For LED fabrication, arrays of small area rectangular, square, or circular geometries could be patterned in the mask. By having these 2-dimensional shapes, the In-incorporation would be further enhanced relative to the stripe geometries since excess group-III adatoms would be arriving from all directions around the growth area, not just from two sides as in narrow stripe geometries. With these arrays the dimension of the LED would be increased by keeping a high Indium composition (˜up to 1 mm). After SAE is completed to grow the high In-containing active layers within these areas, a common p-cladding and/or electrode would be placed over all the light emitting structures such that they can all be activated with a single applied current.

In the above examples, the mask pattern was formed directly on nonpolar/semipolar substrates or on an n-doped layer grown on such substrates. The mask pattern was formed just under the In-containing active layer for SAE to be most effective for In enrichment in layers such as InGaN, InAlGaN and InAlN. Then, the In containing active layer is grown using a high growth temperature for good crystal quality. In this case, the abnormal growth at the edge of the mask pattern could be minimized since the thickness of the SAE is minimized. Often times, the growth rate at the edge of the mask pattern is abnormally high. Thus, at least In containing active layer should be grown using SAE.

In a specific embodiment, we will exploit the growth kinetics of SAE to overcome the difficulties in achieving high-In-content InGaN quantum wells for long wavelength GaN based laser diodes and LEDs on nonpolar/semipolar GaN substrates. This present method and structure apply not only to InGaN layers, but also to all relevant In-containing active layer such as InGaN, InAlGaN and InAlN where increased-In-content layers are desired at high growth temperatures. Not only is our proposed use of SAE an innovative implementation to solve the In-incorporation problem, the concept of doing so on nonpolar/semipolar substrates adds to the novelty of the invention since device fabrication and optimization methods on these substrates is still immature due to their recent availability. The demonstration of efficient laser diodes/LEDs and high In-incorporation on such substrates mentioned above reinforces the viability and promise of our approach for high-efficiency blue/green/yellow/red laser diodes and LEDs.

Other benefits are achieved over conventional techniques. For example, the present method and device achieves high brightness and high resolution lighting technologies that require blue, green, yellow or red contributions such as high resolution red-green-blue displays, communications in polymer-based fibers, or solid-state lighting based on red-greenblue or blue-yellow laser diodes and LEDs. In a specific embodiment, the present invention provides improved crystal quality, highly efficient laser diodes and LEDs on nonpolar/semipolar GaN will enable laser and LED emission in the blue, green, yellow and red bands, allowing the realization of true color displays based on red-green-blue or blue-yellow laser diodes. In a preferred embodiment, the absence of polarization fields in the quantum wells on the substrates along with the increased growth temperatures enabled by SAE will facilitate high efficiency device operation. Thus, this technology would allow for the improvement of existing devices such as 405 nm lasers used in HD-DVD and Sony BlueRay™ along with completely new technologies demanding blue, green, yellow and red emission and low power consumption. Additionally, depending upon the embodiment, the indium concentration is provided preferably within a center region of the growth region and more preferably includes edges regions of the growth region as well. Such indium concentration is generally greater than the use of conventional techniques having larger spatial areas of growth according to a specific embodiment. These and other benefits are described throughout the present specification and more particularly below.

It is believed that the use of SAE for the purpose of realizing high-In-content InGaN layers in lasers diodes and LEDs grown on nonpolar/semipolar GaN substrates has not been proposed prior to this document.

### BRIEF DESCRIPTION OF THE DRAWINGS

FIG. 1 is a simplified diagram illustrating a change in relative concentration of the In and Ga gas phase precursor molecules in the vicinity of a dielectric mask boundary according to an embodiment of the present invention.

FIG. 2 is a simplified plot of In mole fraction as a function of distance from dielectric mask boundary in In and Ga epitaxial layers according to an embodiment of the present invention.

FIG. 3 is a simplified side view schematic of a narrow stripe dielectric mask deposited and patterned on n-GaN layer grown on nonpolar/semipolar substrate according to an embodiment of the present invention.

FIG. 4 is a simplified cross-sectional side-view schematic of a high-In-content quantum well active region grown in the narrow mask opening using SAE according to an embodiment of the present invention.

FIG. 5 is a simplified cross-sectional side-view schematic of a surface ridge laser architecture with dry etched inner ridge for lateral mode confinement according to an embodiment of the present invention.

FIG. 6 is a simplified cross-sectional side-view schematic of buried ridge laser architecture realized with p-GaN cladding over growth of narrow active stripe defined using SAE according to an embodiment of the present invention.

FIG. 7 is a simplified flow diagram of a gallium nitride crystalline growth method according to an embodiment of the present invention.

### DETAILED DESCRIPTION OF THE INVENTION

According to embodiment of the present invention, techniques related generally to optical devices are provided. More particularly, embodiment according to the present invention provides a method and device for emitting electromagnetic radiation using non-polar or semipolar gallium containing substrates such as GaN, MN, InN, InGaN, AlGaN, and AlInGaN, and others. Merely by way of example, the invention can be applied to optical devices, lasers, light emitting diodes, solar cells, photoelectrochemical water splitting and hydrogen generation, photodetectors, integrated circuits, and transistors, among other devices.

The present invention is directed to generate high efficiency GaN-based light emitting devices operating at wavelengths beyond 400 nm for blue, green, yellow and red emission. The proposed device will be used as an optical source for various commercial, industrial, or scientific applications. These structures are expected to find utility in existing applications where blue-violet, blue, green, yellow and red laser/LED emission is required. An existing application includes HD-DVD and Sony Blu-Ray™ players. One particularly promising application for these devices is full color displays requiring red-green-blue or blue-yellow color mixing. Another potential application is for optical communication through polymer based fibers where increased wavelengths will result in reduced loss.

The conventional commercial GaN-based edge-emitting laser diodes and LEDs are grown on c-plane GaN [8-10]. These devices have found applications in several consumer products such as high definition DVD players where the lasers operate at 405 nm. However, when the MOCVD growth conditions are changed to facilitate increased-In content in the quantum well active region to lower the bandgap and increase the operation wavelength, a marked decrease in material quality is observed [1]. A likely candidate for this effect is the reduced growth temperature required to prevent In evaporation as it is well known that crystal quality in ammonia based GaN growth degrades with temperature. The degradation is thought to be a result of poor In mobility in the InGaN wells due to a low temperature growth or due to detrimental strain effects. These limitation have prevented the demonstration of a highly efficient semiconductor laser diode emitting blue, green, yellow or red light.

A laser operating at 488 nm was demonstrated [11]. Although this device offers some promise, it was realized on c-plane GaN where the performance of a device grown on a c-plane GaN will be intrinsically limited by the piezo and spontaneous electric fields inherent to InGaN quantum wells grown in this crystal orientation. The electric fields spatially separate the electron and hole wave functions due to the quantum confined Stark effect thereby reducing the radiative efficiency [3].

SAE has been demonstrated in GaN epitaxial growth for different applications. The most common application is for lateral epitaxial overgrowth (LEO) to create a buffer layer with enhanced crystal quality when growth is performed on mismatched substrates such as SiC and sapphire [12]. However, in this application there is no growth of InGaN layers in the presence of a dielectric mask and thus its intention is clearly not to yield increased-In content InGaN layers. Another application for SAE on c-plane GaN is to create current confinement in surface ridge laser diodes [13]. In this process the dielectric is deposited and patterned after the growth of the n-GaN cladding layer, quantum well active region, and a portion of the p-GaN cladding. Only the remaining p-GaN upper cladding layer is grown with the patterned dielectric on the sample surface. As in LEO, this implementation is clearly not intended for increased-In-composition InGaN since no such layer is grown in the presence of the dielectric mask.

A third application for SAE on c-plane GaN is for the realization of quantum dot like structures where the dielectric mask is patterned to yield small dimensional geometries of growth area [14]. In this application, the InGaN layers were grown in the presence of the dielectric mask and the emission wavelength of the resulting structures was observed to depend on the mask geometries. However, the purpose of the work was to define low dimensional structures using SAE, and not to increase the operation wavelength of edge-emitting laser diodes. Another application of SAE on c-plane GaN is to form multi-color light emitting diode (LED) structures as in [15, 16], where unmasked geometries are patterned in the dielectric mask on the GaN surface. Growth is initiated with a thick n-type GaN layer such that a tall (3-4 μm) mesa is formed, exposing three different crystallographic planes including the semipolar (11-22) plane. After mesa formation, InGaN quantum well layers are grown and capped with a p-type InGaN cladding layer. The resulting compositional differences between the InGaN quantum wells on the different crystal planes leads to multi-wavelength emission. It is very important to note that embodiments according to the present invention will not use SAE for the formation of multiple crystallographic for InGaN growth. Rather, our invention will focus on the growth of high-In-content active layers on the planar growth surface dictated by the nonpolar/semipolar GaN substrate orientation.

In summary, previous work either did not grow the InGaN quantum well layers in the presence of a dielectric mask or the intentions were to form quantum dot like structures or faceting for multi-color LEDs on non-planar surfaces to exploit the differences in the crystallographic planes. Furthermore, none of the aforementioned embodiments of SAE were initiated on nonpolar/semipolar GaN substrates, where enhanced device performance is expected. Details of the present invention can be found throughout the present specification and more particularly below.

Embodiments according to the present invention provide a GaN-based semiconductor laser/LED growth/fabrication method to achieve increased wavelength operation into the blue, green, yellow and red regime on nonpolar/semipolar GaN substrates where superior laser/LED performance can be expected. The device relies on selective area epitaxy (SAE) to enhance the In incorporation in the InGaN quantum well layers grown in narrow unmasked striped regions. The increased diffusion rate of the In containing molecules relative to the Ga containing molecules leads to enriched-In in the In containing layer such as InGaN under identical growth conditions.

The enhanced In incorporation in the epitaxial layer adjacent to the mask region can be understood by the relative decomposition efficiency between TMIn (trimethyl indium) and TMGa (trimethyl gallium), which are In and Ga precursors. It has been shown that the TMIn molecule decomposes more efficiently than TMGa[2]. In this process, the methyl groups are separated from the organic molecules until the In and Ga reside in their atomic form. As decomposition occurs, the radius of the molecule is reduced. Since smaller molecules will more easily diffuse in the gas matrix, the partially decomposed molecules with reduced radii will more readily travel through the MOCVD process gases and arrive at the growth surface where they incorporate into the growing film. The increased efficiency of TMIn decomposition will lead to a smaller average radius for the In containing molecules, increasing the average gas phase diffusion coefficient to a larger extent than the Ga containing molecules. As a result, In is able to migrate to the growth regions adjacent to the mask in greater abundance than the Ga containing molecules, leading to an In-enriched layer. A schematic diagram illustrating the relative concentrations of these molecules with respect to the boundary between the masked and growth region.

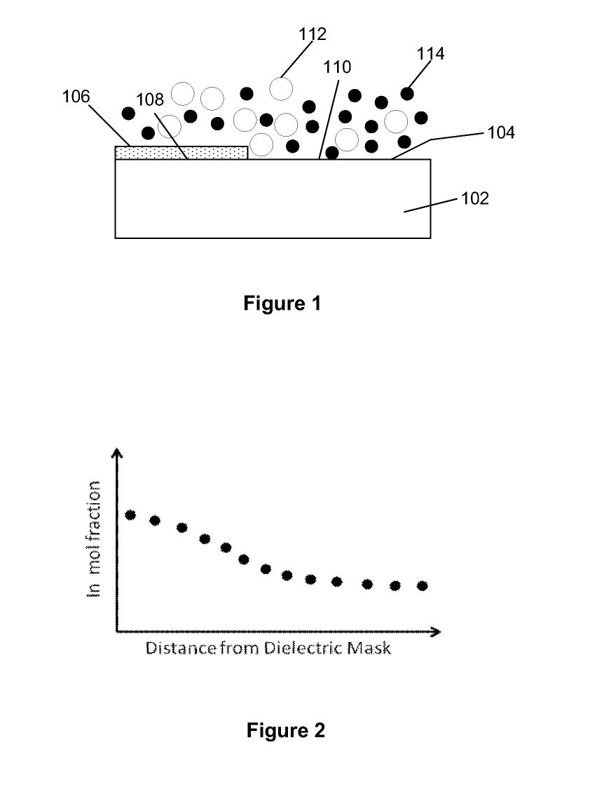

FIG. 1 is a simplified diagram illustrating a method of forming a crystalline gallium indium nitride material according to an embodiment of the present invention. As shown in FIG. 1, a substrate 102 having a surface region 104 is provided. The substrate can be a gallium bearing material in a specific embodiment. In a specific embodiment, the gallium bearing material can include gallium nitride material having desired characteristics. The gallium nitride material has a non-polar characteristics or a semi-polar characteristics in a preferred embodiment. As shown, the method includes depositing a masking layer 106 overlying a portion 108 of the surface region while a growth region 110 remained exposed. The masking layer can be a dielectric material such as silicon oxide, silicon nitride, oxides or nitrides derived from refractory materials (for example, tantalum oxide, tantalum nitride, zirconium oxide, zirconium nitride,) among others. Also shown, above the mask layer far from the boundary there is a relatively high number of Ga containing molecules 112, in the vicinity of the boundary the relative concentration of In molecules 114 becomes higher than Ga, and in the unmasked regions far from the boundary, the relative concentration of each molecule returns to its equilibrium value since it is unaffected by the mask. The resulting film has an In composition that follows the gas phase concentration profile leading to enriched-In films in regions adjacent to the mask as shown in simplified plot in FIG. 2. Such growth kinetics have been exploited for InP and GaAs based devices to modulate the composition and quantum well thickness for monolithic photonic integration [17].

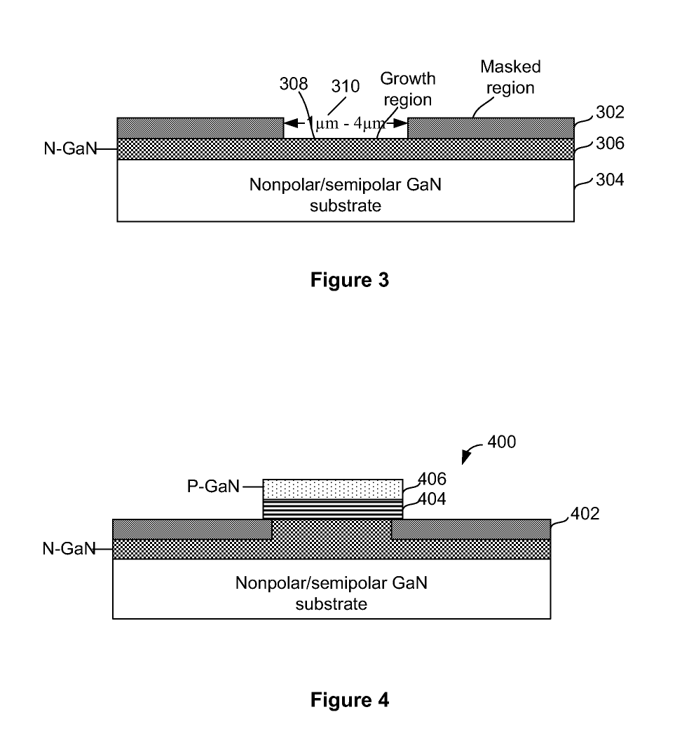

In a specific embodiment, SAE on nonpolar/semipolar GaN substrates, laser fabrication will initiate with the deposition of a dielectric mask 302 either on a substrate 304 itself or on an n-type GaN cladding layer 306 grown on top of the substrate as shown in simplified diagram FIG. 3. This diagram is merely an example and should not unduly limit the claims herein. One skilled in the art would recognize other variations, modifications, and alternatives. As shown the dielectric mask will be lithographically patterned and etched to define narrow (about 1-4 μm) stripes of unmasked area 308. FIG. 3 presents a simplified schematic cross-sectional diagram of such a stripe. The unmasked stripe has a width 310 along with the amount of masked area adjacent to the stripe will determine the growth rate, relative In incorporation, and uniformity of the InGaN layers to be grown. Therefore, careful simulation and experiment must be carried out to optimize the geometry for our intended purpose. After mask patterning step, the sample will be subjected to a MOCVD growth, where the n-GaN cladding layer, the InGaN quantum well active region, and finally a partial or complete p-GaN cladding layer will be grown. In a specific embodiment, the quantum wells are grown in the presence of the dielectric mask such that the InGaN In incorporation is enhanced to provide for an increased emission wavelength for the device.

FIG. 4 is a simplified schematic cross-sectional diagram depicting the resulting epitaxial structure of a high In content quantum well structure 400 according to an embodiment of the present invention. As shown in FIG. 4, a lateral overgrowth of a dielectric mask 402 is expected, and an extent of the lateral overgrowth can be controlled with growth conditions. The high In content quantum well structure includes a n-GaN cladding layer 402, a high In IngaN quantum well active region 404, and a partial or complete p-GaN cladding layer. Beyond the SAE step, there are several fabrication sequences that could be carried out for laser fabrication. The most straightforward would be for a surface ridge laser architecture utilizing the as-grown epitaxial stripe to provide the lateral index contrast for optical wave guiding. In this case, a metal contact would be made to the entire p-GaN cladding layer on the ridge top. Although straightforward, in this embodiment the lateral index discontinuity may be too large for a high power kink-free operation.

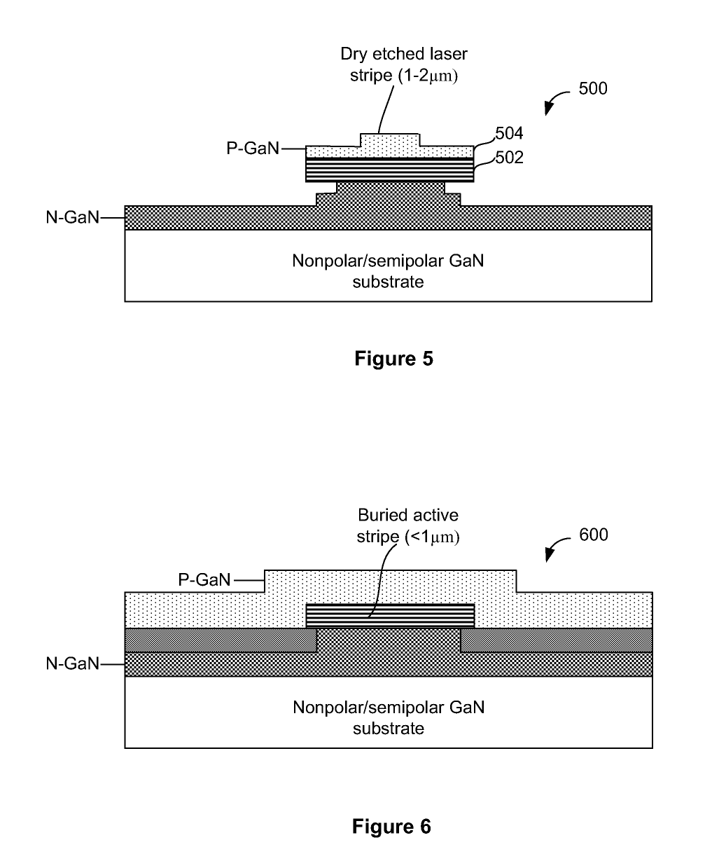

Depending on the embodiment, there can be other variations. In a slightly more complicated surface ridge fabrication sequence, a dry etch step could be included to define a ridge stripe within SAE defined stripe 502 as shown in a simplified cross sectional schematic diagram in FIG. 5. This could be accomplished by removing the dielectric mask from the sample after completion of the growth, performing a blanket dielectric deposition, and then lithographically patterning the dielectric mask to define narrow stripes 504 within the SAE stripe. A dry etch would then be performed to achieve a precisely controlled etch depth to optimize the index contrast versus current confinement trade-off. An example of a possible resulting structure 500 is shown in the simplified cross-sectional schematic diagram in FIG. 5.

In yet another embodiment of this invention, a buried stripe laser architecture 600 could be realized as shown in a simplified cross section diagram in FIG. 6. This would be accomplished by first selectively removing the dielectric mask layer after the SAE growth. The sample would then be subjected to a second growth step to bury the active stripe in the p-GaN cladding layer. A schematic cross-section of this buried stripe architecture is shown in FIG. 6. Although in this embodiment a regrowth is required, it does offer several advantages. The most significant advantage is that very narrow active stripes can be realized since the width is dictated by the dielectric mask opening width, which can be made very narrow ( for example, <1 μm) without introducing excess scattering losses to the optical mode or excess resistance to the p-contact, which typically plagues very narrow surface ridge lasers. The epitaxial interface separating the InGaN active region from the adjacent p-GaN cladding will mitigate the excess scattering loss induced by narrow surface ridge devices where there is high sidewall interaction with the optical mode. The contact resistance can be very low in buried devices because the width of the p-contact will not be limited by the active stripe width. A reduced gain volume of the very narrow stripe widths will allow for reduced threshold currents for a laser of a given length. Furthermore, a buried architecture offers superior heat dissipation characteristic for increased efficiency and reduced threshold current density.

In the preceding paragraphs we have discussed several laser architectures that could be fabricated from our proposed SAE process to achieve high-In-content InGaN quantum wells for increased wavelength operation. It is important to note that there are several other architecture variations in which our SAE approach could be implemented and they should not be excluded from this invention. It is also very important to note again that our invention is exclusive to laser/LED growth/fabrication on nonpolar/semipolar GaN substrates where superior performance is expected relative to devices on polar (c-plane) GaN.

All of the above discussion regarding laser fabrication is easily extended to LED fabrication. LEDs are typically large area devices (500×500 μm) such that the effects of SAE could not exploited over the entire area with only a single region of unmasked growth area. Instead, LEDs would require arrays of small geometry active structures placed under a common cladding layer and/or electrode such that an all light emitting structures in the array could be excited with a single applied current. Although the 1-dimensional narrow stripes required for laser diodes could be used, 2-dimensional geometries such as squares, rectangles, or circles of unmasked areas would offer a further enhancement of In incorporation. This enhancement would result from an arrival of group-III adatoms to the growth area from all directions over the dielectric mask, as opposed to just from two sides as in the case of narrow stripes. That is, the kinetics of SAE near a mask boundary that lead to increased growth rate and In incorporation would be much stronger since the entire growth area in these 2-dimensional geometries would be surrounded by a mask edge.

In this record of invention, we listed several different implementations of SAE for the fabrication of high efficiency laser diodes and LEDs with extended wavelengths. However, there are several other laser/LED fabrication sequences that could be carried out with the use of SAE to increase In content in In containing layer such as InGaN on nonpolar/semipolar substrates. Furthermore, in the above discussion we described very simple dielectric mask patterns consisting of long narrow stripes of unmasked regions for laser diode fabrication. We believe that more complex mask geometries could be implemented to achieve other desired effects. Such effects include modulating the In incorporation along the length of the laser stripe by varying the width of the stripe. This could find use in active/passive integration where regions of high and low bandgap are desired in a single laser diode. An example of this would employ narrow stripe widths in the center region of the laser diode where the lower bandgap light emitting region would reside and wide stripe widths at the ends of the laser diodes for an increased bandgap that would be transparent to emitted light. If mirror facets of the laser were placed in the passive region, an onset of catastrophic facet damage can be delayed.

In the case of LED fabrication, we mentioned the use of simple 2-dimensional mask pattern geometries such as rectangles, squares, and circles. However, this invention should not exclude more complex 2-dimensional geometries that could be beneficial to the performance of an LED. In summary, any laser or LED fabrication method that relies on SAE to achieve high-quality, high In-content layers such as InGaN on nonpolar/semipolar GaN substrates for blue/green/yellow/red laser and LED emission should not be excluded from the breadth of this invention.

Embodiments according to the present invention provide high-brightness blue and green LEDs and can be used to make white LEDs with a combination of conventional AlInGaP red LEDs. Embodiments according to the present invention can be used to combine blue LEDs with a phosphor such as YAG to create white LEDs. Furthermore, we could add a conventional AlInGaP red LED into Blue/YAG phosphor white LEDs to improve the color rendering.

This invention provides methods and devices that offer a promising alternative technique to realize high-In-content films such as InGaN, InAlGaN, and InAlN on nonpolar/semipolar GaN substrates. Conventional methods for achieving high-In-content InGaN films rely on non-standard growth conditions that result in degraded material quality. For example, in conventional MOCVD growth the temperature must be reduced to limit the In evaporation. Our invention exploits SAE to alter the local growth kinetics to realize enhanced In incorporation, such that InGaN layer growth can be performed at relatively high temperature to improve the crystal quality. Due to this reason, embodiments according to the present invention should be applicable to all kinds of In containing layers such as InGaN. InAlGaN, InAlN, and others for any In composition to improve the crystal quality of the layer at a higher growth temperature. This provides for means to fabricate high efficient light emitting devices at any wavelength with a high quality In containing layer. For the SAE process described above, a simple dielectric mask is employed to enhance the concentration of In-containing molecules in the unmasked growth regions. InGaN films grown using this technique should therefore demonstrate enhanced In incorporation without the need for non-standard growth conditions that can degrade material quality. In addition, the masking layer is not limited to a dielectric mask. The use of any other mask materials such as metals and others upon which SAE can be performed should not be excluded from this invention.

A epitaixial growth method according to the present invention may be outlined below.

1. Start;

2. Providing a non-polar or semi-polar gallium nitride containing substrate having a surface region;

3. Form a dielectric masking layer overlying the surface region to expose a growth region, which is substantially exposed gallium nitride crystalline material having a spatial dimension of no greater than about ten microns in one of a narrowest dimension, but can be others;

4. Load the non-polar or semi-polar gallium nitride containing substrate onto a susceptor in a reaction chamber;

5. Cause an increase or maintain the susceptor at a temperature ranging from about 600 Degree Celsius to about 1200 Degree Celsius;

6. Introduce an indium precursor species;

7. Introduce nitrogen bearing species;

8. Introduce gallium species;

9. Combine the indium precursor species, nitrogen bearing species, and gallium species;

10. Initiate selective growth of a crystal material including indium gallium nitride within the exposed reaction region;

11. Maintain the dielectric masking layer substantially free from growth of any crystalline material of the indium gallium nitride;

12. Maintain a reaction temperature of about 600 Degrees Celsius to about 1200 Degrees Celsius for the crystal material capable of emitting visible light and the crystalline material having higher indium concentration compared to an indium concentration provided on a growth region of greater than about 15 microns (or other dimension) such than one or more of the indium species diffuses at a faster rate than one or more of the gallium species to cause the higher indium concentration at the growth region;

13. Cause formation of an indium gallium nitride containing film; and

14. Perform other steps, as desired.

The above sequence of steps provides a method of forming a crystalline indium gallium nitride film capable of emitting light in a wavelength range of 400 nm to 780 nm, and others. In a specific embodiment, the molar concentration of indium in the resulting crystalline indium gallium nitride material may vary and preferably increase depending on a spatial width of the growth region thereby affecting the wavelength of the emitting light. Of course one skilled in the art would recognize other variations, modifications, and alternatives.

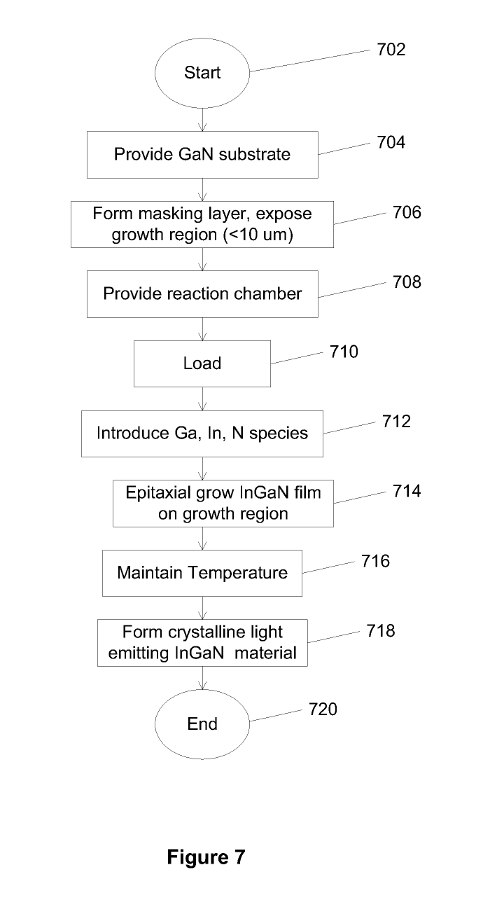

FIG. 7 is a simplified flow diagram illustrating a method of forming a crystalline gallium indium nitride film according to an embodiment of the present invention. As shown, the method includes a start step (step 702), as an initial step. In a specific embodiment, a gallium nitride substrate is provided (Step 704). In a preferred embodiment, the gallium nitride substrate has a semi-polar or a non-polar characteristics. As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and 1 is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k l) plane wherein l=0, and at least one of h and k is non-zero). Of course, there can be other variations, modifications, and alternatives.

A masking layer is formed overlying a first region of the surface region and a growth region is exposed (Step 706) according to a specific embodiment. The masking layer is commonly a hard mask made of silicon dioxide, nitride, or other suitable materials according to a specific embodiment. The masking layer (or layers) is patterned using common techniques to form exposed regions. In a specific embodiment, the exposed regions are exposed regions of gallium nitride, which will be subjected to a further process or processes. In a specific embodiment, the exposed region is also a growth region being substantially exposed gallium nitride crystalline material. The growth region has a spatial width dimension of no greater than about ten microns in one of a narrowest dimension, but can be others. In certain embodiments, the spatial width dimension can be no greater than about 7 microns or no greater than about 4 microns or no greater than about 2 microns. In a specific embodiment, the spatial width dimension can be no greater than about 4 microns or no greater than about 6 microns. Again, there can be other variations, which are explained below.

For example, one or more growth regions may be formed. The one or more growth regions can be configured as one or more strips arranged in a parallel configuration relative to each other. Each of the strips may also have a substantially similar width or different widths. Also depending on the application, at least one of the growth regions may be configured with a modulated width having a first dimension and a second dimension. Each of the one or more growth regions may also comprise a plurality of growth regions, arranged in an N by M array configuration, where N and M are integers greater than 1. The one or more of the plurality of growth regions may be configured with one or more spatial structures, including annular, trapezoidal, square, circular, polygon shaped, amorphous shaped, irregular shaped, triangular shaped, or any combinations of these, and others. In a specific embodiment, the array configuration of the grow regions provides for a light emitting diode device.

In a specific embodiment, the method provides a reaction chamber including a susceptor configured at a temperature ranging from about 600 Degree Celsius to about 1200 Degree Celsius (Step 708). In a preferred embodiment, the reaction chamber is a suitable MOCVD reactor for depositing epitaxial films of gallium nitride containing films, among others. Of course, there can be other variations, modifications, and alternatives. In a specific embodiment, the substrate including the masking layer is loaded onto the susceptor (Step 710). The susceptor is configured to provide a selected temperature for processing and crystalline growth.

Next, the method includes one or more processes to introduce precursor species and/or gases for formation of the gallium nitride epitaxial layer. In a specific embodiment, precursors species including at least a gallium bearing species, an indium bearing species, and a nitrogen bearing species are introduced into the reaction chamber (Step 712) and initiate an epitaxial growth of a gallium indium nitride film material (Step 714) overlying the exposed growth region. As an example, precursor gases include TMGa, TMIn, TEGa, among others. Of course, there can be other variations, modifications, and alternatives.

In a specific embodiment, the reaction chamber may be maintained at about atmospheric pressure for the growth of the gallium nitride film material. The reaction chamber may also be maintained at about 700 torr to no greater than 850 torr for the growth of the gallium nitride film material. Still, the reaction chamber may be maintained at about 1 Torr to about 760 Torr depending on the embodiment. Other pressures may also exist in suitable combination with other process parameters. Of course there can be other variations, modifications, and alternatives.

In a preferred embodiment, the method maintains the temperature at about 600 Degree Celsius to about 1200 Degree Celsius for a period of time (Step 716) while forming a crystalline indium gallium nitride material (Step 718). In a specific embodiment, the crystalline gallium nitride is formed overlying the growth region. In a specific embodiment, the crystalline indium gallium nitride material is capable of emitting light at a wavelength ranging from about 400 nm to about 780 nm. In a preferred embodiment, the method maintains a reaction temperature of about 600 Degrees Celsius to about 1200 Degrees Celsius for the crystal material capable of emitting visible light. Preferably, the crystalline material has higher indium concentration compared to an indium concentration provided on a growth region that is larger, such as, for example, greater than about 15 microns. It is believed that one or more of the indium species diffuses at a faster rate than one or more of the gallium species to cause the higher indium concentration at the growth region using the smaller growth region. The indium concentration is characterized by about 20 to 50% molar concentration in a specific embodiment. In a specific embodiment, the indium concentration can range from about 30% to about 45% for 520 nanometer light emission. The indium gallium nitride film can also have an indium mole fraction ranging from about 1% to about 20% in the narrowest dimension of the growth region in a specific embodiment. The indium gallium nitride film can have an indium mole fraction in the ranging from about 20% to about 40% in the narrowest dimension of the growth region in an alternative embodiment. Yet in other embodiments, the indium gallium nitride film can have an indium mole fraction ranging from about 40% to about 60% in the narrowest dimension of the growth region or even up to about 60% to about 80% in the narrowest dimension of the growth region. Other suitable processes for forming layers (e.g., quantum well, electrode) in optical devices are also included. As shown, the method stops with an end step (Step 720). Of course, there can be other variations, modifications, and alternatives.

The above sequence of steps provides a method of forming a crystalline indium gallium nitride film capable of emitting light in a wavelength range of 400 nm to 780 nm. In a specific embodiment, the molar concentration of indium in the resulting crystalline indium gallium nitride material may vary (preferably higher) depending on a spatial width of the growth region thereby affecting the quality of the gallium material and the wavelength of the emitting light. Of course one skilled in the art would recognize other variations, modifications, and alternatives.

In a specific embodiment, a gallium containing crystalline material is provided. The gallium containing crystalline material includes a bulk non-polar gallium and indium containing crystalline material having a thickness of about 20 nanometers to about 1000 nanometers. In a specific embodiment, the thickness of the bulk non-polar gallium indium containing crystalline material is characterized by a spatial width dimension of no greater than about 10 microns. Depending on the embodiment, the spatial width dimension may be no greater than 7 microns or no greater than 4 microns or no greater than 2 micron. In a specific embodiment, the crystalline material has a photoluminescent characteristic of having a first wavelength. The first wavelength is at least five nanometers greater than a second wavelength. The second wavelength is derived from an indium and gallium containing crystalline material grown on a growth region of greater than about 15 microns.

In a specific embodiment, an optical device capable of emitting light is provided. The optical device includes a gallium containing substrate structure having a surface region. The optical device includes a region of insulating material having one or more growth regions provided on the surface region. The insulating material can be selected from silicon dioxide, silicon nitride, tantalum oxide, titanium oxide, zirconia oxide, or zinc oxide, but can be others. The one or more growth regions are one or more exposed regions of the surface region in a specific embodiment. In a specific embodiment, the optical device includes a non-polar gallium indium containing crystalline material provided on a portion of one or more of the growth regions of the gallium containing substrate structure. The non-polar gallium indium containing crystalline material can have a thickness of about 1 nanometers to about 20 nanometers in a specific embodiment. A spatial width dimension of no greater than about 10 microns characterizes each of the one or more growth regions in a specific embodiment. The crystalline material has a first indium concentration characteristic. The first indium concentration characteristic is greater than a second indium concentration characteristic by at least about 1 percent in a specific embodiment. The second indium concentration characteristic is derived from an indium gallium containing crystalline material grown on a growth region of greater than about 15 microns in a specific embodiment.

Depending on the embodiment, the spatial width dimension of the growth region can be no greater than about 7 microns or no greater than about 4 microns or no greater than about 2 microns. In certain embodiments, the spatial width dimension is no greater than about 6 microns. Again depending on the embodiment, the first indium concentration can be characterized by about 20 to 50% molar concentration. As merely an example, the first indium concentration can range from about 30% to about 45% for a 520 nanometer light emission device.

Again, depending on the application, the optical device can have the one or more growth regions configured as one or more strips. Each of the strips is arranged in a parallel configuration relative to each other in a specific embodiment. Each of the strips can have a substantially similar width or different widths depending on the embodiment. In certain embodiments, at least one of the growth regions is configured with modulated widths having a first dimension and a second dimension. The first dimension can be the same as the second dimension. The first dimension can also be different from the second dimension in a specific embodiment.

The one or more growth regions may further include a plurality of growth regions. The plurality of growth regions can be arranged in an N by M array configuration to provide for a light emitting diode device, where N and M are integers greater than 1. The plurality of growth regions may also be configured with one or more spatial structures. The one or more spatial structures is selected from annular, trapezoidal, square, circular, polygon shaped, amorphous shaped, irregular shaped, triangular shaped, or any combinations of these, and others.

In a specific embodiment, the optical device is capable of emitting light in one or more of a plurality of selected wavelengths. The selected wavelengths range from about 480 to about 570 nanometer range depending on the spatial width dimension. Of course there can be other variations, modifications, and alternatives.

While the above is a full description of the specific embodiments, various modifications, alternative constructions and equivalents may be used. Therefore, the above description and illustrations should not be taken as limiting the scope of the present invention which is defined by the appended claims.

### Cited Art

The following journal articles are relevant to this document:

[1] M. Funato, M. Ueda, Y. Kawakami, Y. Narukawa, T. Kosugi, M. Takahashi, and T. Mukai, “Blue, Green, and Amber InGaN/GaN Light-Emitting Diodes on Semipolar {11-22) GaN Substrates,” Journal of Japanese Applied Physics, Vol. 45, No. 26, pp. 659-662, 2006.

[2] C. Caneau, R, Bhat, M. R. Frei, C. C. Chang, R. J. Deri, and M. A. Koza, “Studies on Selective OMVPE of (Ga,In)/(As,P),” Journal of Crystal Growth. vol. 124 pp. 243-248. 1992.

[3] F. Bernardini, V. Fiorentini, and D. Vanderbilt, “Spontaneous polarization and piezoelectric constants of III-V nitrides,” Physical Review B, Vol. 56, No. 16, pp. 1002410027, October 1997.

[4] P. Waltereit, O. Brandt, A. Trampert, H. Grahn, J. Menniger, M. Ramsteiner, M. Reiche, and K. Ploog, “Nitride semiconductors free of electrostatic fields for efficient white light-emitting diodes,” Nature, Vol. 406, pp. 865-868, August 2000.

[5] M. Schmidt, K. C. Kim, R. M. Farrell, D. F. Feezell, D. A. Cohen, M. Saito, K. Fujito, J. S. Speck, S. P. DenBaars, and S. Nakamura, “Demonstration of Nonpolar m-plane InGaN/GaN Laser Diodes,” Journal of Japanese Applied Physics, Vol. 46, No. 9, pp. 190191, 2007.

[6] K. Okamoto, T. Tanaka, M. Kubota, and H. Ohta, “Pure Blue Laser Diodes Based on Nonpolar m-Plane Gallium Nitride with InGaN Waveguiding Layers,” Journal of Japanese Applied Physics, Vol. 46, No. 35, pp. 820-822, 2007.[7] H. Sato, A. Tyagi, H. Zhong, N. Fellows, R. B. Chung, M. Saito, K. Fujito, J. S. Speck, S. P. DenBaars, and S. Nakamura “High power and high efficiency green light emitting diode on free-standing semipolar (11-22) bulk GaN substrate” Phys. Stat. Sol, Vol. 1, no. 4, pp. 162-164, 2007.

[8] S. Nakamura, M. Senoh, S. Nagahama, N. Iwasa, T. Yamada, T. Matsushita, H. Kiyoku, Y. Sugimoto, T. Kozaki, H. Umemoto, M. Sano, and K. Chocho, “InGaN/Gan/AlGaN-based laser diodes with modulation-doped strained-layer superlattices grown on an epitaxially laterally grown GaN substrate”, Applied Physics Lefts., Vol. 72, No. 12, pp. 211-213, Jan. 12, 1998.

[9] T. Asano, T. Tsuyoshi, T. Mizuno, M. Takeya, S. Ikeda, K. Shibuya, T. Hino, S. Uchida, and M. Ikeda, “100-mW kink-free blue-violet laser diodes with low aspect ratio,” IEEE Journal of Quantum Electronics, Vol. 39, No. 1, pp. 135-140, January 2003.

[10] S. Uchida, M. Takeya, S. Ikeda, T. Mizuno, T. Fujimoto, O. Matsumoto, S. Goto, T. Tojyo, and M. Ikeda, “Recent progress in high-power blue-violet lasers,” IEEE Journal of Selected Topics in Quantum Electronics, Vol. 9, No. 5, pp. 1252-1259, September/October 2003.

[11] hap://techon.nikkeibp. co jp/english/NEWS_EN/20080122/146009/

[12] O. H. Nam, T. S. Zheleva, M. D. Bremser, and R. F. Davis, “Later epitaxial overgrowth of GaN films on SiO2 areas via metalorganic vapor phase epitaxy,” Journal of Electronic Materials, Vol. 27, No. 4, pp. 233-237, April 1998.

[13] M. Kuramoto, A. Kimura, C. Sasaoka, T. Arakida, M. Nido, and M. Mizuta, “Novel Ridge-Type InGaN Multiple-Quantum-Well Laser Diodes Fabricated by Selective Area Re-Growth on n-GaN Substrates,” Journal of Japanese Applied Physics, Vol. 40, pp. 925-927, September 2007.

[14] P. Chen, A. Chen, S. Jin Chua, and J. N. Tan, “Growth and Optical Properties of Highly Uniform and Periodic InGaN Nanostructures,” Advanced Materials, vol. 19, pp. 1707-1710, 2007.

[15] H. Yu, T. Jung, L. K. Lee, and P. C. Ku, “Multiple Wavelength Emission from Semipolar InGaN/GaN Quantum Wells Selectively Grown by MOCVD.”

[16] M. Funato, T. Kondou, K. Hayashi, S. Nishiura, M. Ueda, Y. Kawakami, Y. Narukawa, and T. Mukai, “Monolithic Polychromatic Light-Emitting Diodes Based on InGaN Microfacet Quantum Wells toward Tailor-Made Solid-State Lighting,” Applied Physics Lefts., Vol. 1, 2008.

[17] M. Aoki, M. Suzuki, H. Sano, T. Kawano, T. Ido, T. Taniwatari, K. Uomi, and A. Takai, “InGaAs/InGaAsP MQW Electroabsorption Modulator Integrated with a DFB Laser Fabricated by Band-Gap Energy Control Selective Area MOCVD,” IEEE J Quantum Electron., vol. 29, pp. 2088-2096, 1993.

What is claimed is:

1. A method for processing one or more precursor species to form a gallium containing film, the method comprising:
providing a non-polar or semi-polar gallium nitride containing substrate having a surface region;
forming a dielectric masking layer overlying the surface region to expose a growth region, the growth region being substantially exposed gallium nitride crystalline material, the growth region having a spatial dimension of no greater than about ten microns in one of a narrowest dimension;
loading the non-polar or semi-polar gallium nitride containing substrate onto a susceptor in a reaction chamber, the susceptor being at a temperature ranging from about 600 Degree Celsius to about 1200 Degree Celsius;
introducing an indium precursor species into the chamber;
introducing nitrogen bearing species into the chamber;
introducing gallium species into the chamber;
combining the indium precursor species, nitrogen bearing species, and gallium species;
initiating selective growth of a crystal material including indium gallium nitride within the exposed reaction region while maintaining the dielectric masking layer substantially free from growth of any crystalline material of the indium gallium nitride; and
maintaining a reaction temperature of about 600 Degrees Celsius to about 1200 Degrees Celsius for the crystal material capable of emitting visible light and the crystalline material having higher indium concentration compared to an indium concentration provided on a growth region of greater than about 15 microns such than one or more of the indium species diffuses at a faster rate than one or more of the gallium species to cause the higher indium concentration at the growth region; and
forming an indium gallium nitride containing film.

2. The method of claim 1 wherein the masking layer inhibits an epitaxial growth of the indium gallium nitride.

3. The method of claim 1 wherein the indium gallium nitride containing film comprising an indium mole fraction in the indium gallium nitride film, the mole fraction being about 1% to about 20% in the narrowest dimension of the growth region.

4. The method of claim 1 wherein the indium gallium nitride containing film comprising an indium mole fraction in the indium gallium nitride film, the mole fraction being about 20% to about 40% in the narrowest dimension of the growth region.

5. The method of claim 1 wherein the indium gallium nitride containing film comprising an indium mole fraction in the indium gallium nitride film, the mole fraction being about 40% to about 60% in the narrowest dimension of the growth region.

6. The method of claim 1 wherein the indium gallium nitride containing film comprising an indium mole fraction in the indium gallium nitride film, the mole fraction being about 60% to about 80% in the narrowest dimension of the growth region.

7. The method of claim 1 wherein the indium precursor comprises a trimethylindium species.

8. The method of claim 1 wherein the gallium species comprises a trimethylgallium species.

9. The method of claim 1 wherein the gallium species comprises a triethylgallium species.

10. The method of claim 1 wherein the dielectric masking layer is made of a material selected from silicon dioxide, silicon nitride, or any other thin film layer that inhibits growth on a surface of the dielectric masking layer.

11. The method of claim 1 further comprising maintaining the chamber at about atmospheric pressure.

12. The method of claim 1 further comprising maintaining the chamber at about 700 torr to no greater than 850 torr.

13. The method of claim 1 further comprising maintaining the chamber at about 1 Torr to about 760 Torr.

14. A gallium containing crystalline material comprising:
a bulk non-polar gallium and indium containing crystalline material having a thickness of about 20 nanometers to about 1000 nanometers;
a spatial width dimension of no greater than about 10 microns characterizing the thickness of the bulk non-polar gallium indium containing crystalline material; and
a photoluminescent characteristic of the crystalline material having a first wavelength, the first wavelength being at least five nanometers greater than a second wavelength, the second wavelength being derived from an indium and gallium containing crystalline material grown on a growth region of greater than about 15 microns.

15. The material of claim 14 wherein the spatial width dimension is no greater than 7 microns or no greater than 4 microns or no greater than 2 microns.

16. An optical device capable of emitting light at a wavelength ranging from about 480 nanometers to about 570 nanometers comprising:
a gallium containing substrate structure having a surface region;
a region of insulating material having one or more growth regions provided on the surface region, the one or more growth regions being one or more exposed regions of the surface region;
a semi-polar gallium indium containing crystalline material provided on a portion of one or more of the growth regions of the gallium containing substrate structure, the semi-polar gallium indium containing crystalline material having a thickness of about 1 nanometers to about 20 nanometers;
a spatial width dimension of no greater than about 10 microns characterizing each of the one or more growth regions; and
a first indium concentration characteristic of the crystalline material, the first indium concentration characteristic being greater than a second indium concentration characteristic by at least about 1 percent, the second indium concentration characteristic being derived from an indium gallium containing crystalline material grown on a growth region of greater than about 15 microns.

17. The device of claim 16 wherein the spatial width dimension is no greater than 7 microns or no greater than 4 microns or no greater than 2 microns.

18. An optical device capable of emitting light in about 480 nanometers to about 570 nanometers wavelength range comprising:
a gallium containing substrate structure having a surface region;
a region of insulating material having one or more growth regions provided on the surface region, the one or more growth regions being one or more exposed regions of the surface region;
a non-polar gallium indium containing crystalline material provided on a portion of one or more of the growth regions of the gallium containing substrate structure, the non-polar gallium indium containing crystalline material having a thickness of about 1 nanometers to about 20 nanometers;
a spatial width dimension of no greater than about 10 microns characterizing each of the one or more growth regions; and
a first indium concentration characteristic of the crystalline material, the first indium concentration characteristic being greater than a second indium concentration characteristic by at least about 1 percent, the second indium concentration characteristic being derived from an indium gallium containing crystalline material grown on a growth region of greater than about 15 microns.

19. The device of claim 18 wherein the spatial width dimension is no greater than about 7 microns or no greater than about 4 microns or no greater than about 2 microns.

20. The device of claim 18 wherein the spatial width dimension is no greater than about 4 microns.

21. The device of claim 18 wherein the spatial width dimension is no greater than about 6 microns.

22. The device of claim 18 wherein the first indium concentration is characterized by about 20 to 50% molar concentration.

23. The device of claim 18 wherein the first indium concentration ranges from about 30% to about 45% for 520 nanometer light emission.

24. The device of claim 18 wherein the one or more growth regions is configured as one or more strips, each of the strips being arranged in a parallel configuration relative to each other.

25. The device of claim 18 wherein each of the strips having a substantially similar width or different widths.

26. The device of claim 18 wherein at least one of the growth regions is configured with a modulated width, the width having a first dimension and a second dimension.

27. The device of claim 18 wherein the one or more growth regions comprises a plurality of growth regions, the plurality of growth regions being arranged in an array configuration, the array configuration being defined by N and M, where N and M are integers greater than 1.

28. The device of claim 27 wherein one or more of the plurality of growth regions is configured with one or more spatial structures, the one or more spatial structures being selected from annular, trapezoidal, square, circular, polygon shaped, amorphous shaped, irregular shaped, triangular shaped, or any combinations of these.

29. The device of claim 27 wherein the array configuration is for a light emitting diode device.

30. The device of claim 18 wherein the region of insulating material is selected from silicon dioxide, silicon nitride, tantalum oxide, titanium oxide, zirconia oxide, or zinc oxide.

31. The device of claim 18 wherein the spatial width dimension is configured to emit one or more of a plurality of selected wavelengths, the wavelengths ranging from about 480 to about 570 nanometer range.

32. A gallium containing crystalline material comprising:
a bulk semi-polar gallium indium containing crystalline material having a thickness of about 20 nanometers to about 1000 nanometers;
a spatial width dimension of no greater than about 10 microns characterizing the thickness of the bulk semi-polar gallium indium containing crystalline material; and
a photoluminescent characteristic of the crystalline material having a first wavelength, the first wavelength being at least five nanometers greater than a second wavelength, the second wavelength being derived from an indium gallium containing crystalline material grown on a growth region of greater than about 15 microns.

33. An optical device capable of emitting light in about 400 nanometer to about 480 nanometer wavelength range, comprising:
a gallium containing substrate structure having a surface region;
a region of insulating material having one or more growth regions provided on the surface region, the one or more growth regions being one or more exposed regions of the surface region;
a semi-polar gallium indium containing crystalline material provided on a portion of one or more of the growth regions of the gallium containing substrate structure, the semi-polar gallium indium containing crystalline material having a thickness of about 1 nanometers to about 20 nanometers;
a spatial width dimension of no greater than about 10 microns characterizing each of the one or more growth regions; and
a first indium concentration characteristic of the crystalline material, the first indium concentration characteristic being greater than a second indium concentration characteristic by at least about 1 percent, the second indium concentration characteristic being derived from an indium gallium containing crystalline material grown on a growth region of greater than about 15 microns.

34. The device of claim 33 wherein the spatial width dimension is no greater than 7 microns or no greater than 4 microns or no greater than 2 microns.

35. An optical device capable of emitting light in about 570 nanometer to about 660 nanometer wavelength range, comprising:
a gallium containing substrate structure having a surface region;
a region of insulating material having one or more growth regions provided on the surface region, the one or more growth regions being one or more exposed regions of the surface region;
a semi-polar gallium indium containing crystalline material provided on a portion of one or more of the growth regions of the gallium containing substrate structure, the semi-polar gallium indium containing crystalline material having a thickness of about 1 nanometers to about 20 nanometers;
a spatial width dimension of no greater than about 10 microns characterizing each of the one or more growth regions; and
a first indium concentration characteristic of the crystalline material, the first indium concentration characteristic being greater than a second indium concentration characteristic by at least about 1 percent, the second indium concentration characteristic being derived from an indium gallium containing crystalline material grown on a growth region of greater than about 15 microns.

36. The device of claim 35 wherein the spatial width dimension is no greater than 7 microns or no greater than 4 microns or no greater than 2 microns.

37. A method for forming a crystalline gallium indium nitride film, the method comprising:
providing a gallium nitride substrate having a surface region; the gallium nitride substrate having a non-polar characteristics or a semi-polar characteristics, the gallium nitride substrate having a crystalline characteristics
forming a masking layer overlying a first region of the surface region while a growth region remained exposed, the growth region having a spatial dimension characterized by about ten microns or less in one of a narrowest dimension;
loading the gallium nitride substrate including the masking layer into a reaction chamber, the reaction chamber being characterized by a height, a width, and a length, the reaction chamber being configured to provide a temperature ranging from about 600 Degree Celsius to about 1200 Degree Celsius;
introducing at least an indium bearing species, a nitrogen bearing species, and a gallium bearing species into the reaction chamber;
initiating an epitaxial growth of at least a indium gallium nitride material overlying the exposed growth region while maintaining the first region substantially free from growth of any indium gallium nitride material;
maintaining a reaction temperature of about 600 Degrees Celsius to about 1200 Degrees Celsius for a pre-determined period of time; and
forming a first crystalline indium gallium nitride material overlying the growth region, the first crystalline indium gallium nitride material being capable of emitting a visible light in a wavelength range comprising 400 nm to 780 nm;
wherein the indium precursor species diffuses at a faster rate than the gallium bearing species in a vicinity of a surface region of the growth region to cause a higher indium concentration in the first crystalline indium gallium nitride material in the growth region,
wherein the first crystalline indium gallium nitride material has a first indium concentration in the growth region having a first spatial and a second indium concentration provided on a growth region having a second spatial width greater than the first spatial width, the first indium concentration is greater than the second indium concentration.

38. The method of claim 37 wherein the first crystalline indium gallium nitride material is semi-polar or non-polar.

39. A gallium containing crystalline material comprising:
a thickness of non-polar or semi-polar gallium and indium containing crystalline material having a thickness ranging from about 20 nanometers to about 1000 nanometers;
a spatial width dimension characterizing the thickness of non-polar or semi-polar gallium and indium containing crystalline material; and
a photoluminescent characteristic, the photoluminescent characteristic being characterized by a wavelength, the wavelength being dependent on the spatial width dimension, a first wavelength being associated with a first spatial width dimension, the first width dimension being less than about 10 microns, a second wavelength being associated with a second spatial width dimension, the second spatial width dimension being grater than about 15 microns, the first wavelength being at least five nanometers greater than a second wavelength.

40. A light emitting optical device structure, comprising:
a gallium containing substrate structure having a surface region;
a insulating material overlying a first region of the surface region;
one or more growth regions, the one or more growth regions being one or more exposed regions of the surface region; and
a semi-polar gallium indium containing crystalline material overlying a portion of the one or more of growth regions, the semi-polar gallium indium containing crystalline material having a thickness of about 1 nanometers to about 20 nanometers;
wherein each of the one or more growth regions is characterized by a spatial width dimension of no greater than 10 microns; the spatial width dimension is associated with an indium concentration of the semi-polar gallium indium containing crystalline material.

41. The device of claim 40 wherein the growth region has a spatial dimension of no greater than 7 microns or no greater than 4 microns or no greater than 2 microns.

42. The device of claim 40 wherein the indium concentration is about 20% to about 50% molar concentration.

43. The device of claim 40 wherein the indium concentration ranges from about 30% to about 45% molar concentration.

44. The device of claim 43 is further characterized by a capability to emit light having a wavelength at about 520 nanometers.

45. The device of claim 40 is further characterized by a capability of emitting light at a wavelength ranging from about 480 nanometers to about 570 nanometers.

46. The device of claim 40 is further characterized by a capability of emitting light at a wavelength ranging from about 400 nanometers to about 480 nanometers.

47. The device of claim 40 is further characterized by a capability of emitting light at ranging from about 570 nanometers to about 660 nanometers wavelength range.

48. The device of claim 40 wherein the growth region is overlaid by a non-polar gallium indium containing crystalline material.
